(19) United States
(12) Patent Application Publication
(10) Pub. No.: US 2026/0353854 A1
(43) Pub. Date: Nov. 5, 2026

(54) HETEROJUNCTION SOLAR CELL STRUCTURE

(71) Applicant: SEG Solar Inc., Houston, TX (US)

(72) Inventors: Jun Zhuge, Cypress, TX (US); Hui Huang, Nanchang (CN); Jian Zhou, Taizhou City (CN); Weidong Ai, Puyang (CN)

(73) Assignee: SEG Solar Inc., Houston, TX (US)

(21) Appl. No.: 19/565,147

(22) Filed: Mar. 12, 2026

Related U.S. Application Data
(60) Provisional application No. 63/798,728, filed on May 2, 2025.

(51) Int. Cl. H10F 77/20; H10F 10/164; H10F 71/00

(52) U.S. Cl. CPC H10F 77/215; H10F 10/164; H10F 71/138

(57) ABSTRACT

A heterojunction solar cell includes a silicon substrate, a passivation layer overlaying the silicon substrate at a first surface, a first indium tin oxide (ITO) layer overlaying the passivation layer, a second indium tin oxide (ITO) layer overlaying the first ITO layer, and metal grid lines between the first and second ITO layers.

### CROSS-REFERENCE TO RELATED APPLICATION

This application takes priority from U.S. Provisional Patent Application No. 63/798,728 filed May 2, 2025, the contents of which are incorporated by reference herein in their entirety.

### FIELD OF THE INVENTION

The invention relates to a structure and manufacturing method for heterojunction (HJT) solar cells. In particular, the invention relates to heterojunction solar cells manufactured using a stepwise coating method and containing embedded fine grid lines.

### BACKGROUND

Heterojunction solar cells are a known family of photovoltaic solar cell technologies based on a heterojunction formed between semiconductors with dissimilar band gaps.

Silicon heterojunction based solar panels have become very popular in recent years and generally include a crystalline silicon substrate passivated by a thin layer of hydrogenated intrinsic amorphous silicon (a-Si:H) provided as a buffer layer. An overlay may then be formed of indium tin oxide (ITO), providing a transparent conducting oxide (TCO), applied as a transparent electrode film. Electrodes, in the form of grid lines, may then be printed onto the ITO film.

The silicon heterojunction is formed by selective contacts, also referred to as window layers, integrated into the passivation layer. Accordingly, the passivation layer typically comprises a first “intrinsic,” or undoped, silicon layer (a-Si:H(i)) and a second, doped, silicon layer (a-Si:H(n) or a-Si:H(p)). In the design discussed herein, the solar cell may be bifacial, with an n-doped layer on one surface and a p-doped layer on an opposite surface.

Typical silver paste screen printing methods, which include sintering, require firing at up to 800° Celsius. However, such approaches cannot be used in the context of HJT solar cells, since such temperatures would damage the underlying layers of the HJT solar cell. In particular, the passivation layer would be destroyed by such high temperatures. However, direct printing of grid lines on a single-layer ITO film results in an unacceptable contact resistance (typically greater than 1.0 mΩ·cm²).

Any high-temperature silver paste sintering, utilizing temperatures greater than 200° Celsius, results in damage to the interface characteristics of the amorphous silicon passivation layer.

Further, exposing the grid lines by printing them directly onto the ITO film without high temperature sintering could lead to oxidation failure, which would result in power degradation over time. This may occur at a rate of greater than .5% per year in a hot and humid environment, and results in an unacceptable loss of efficiency.

There is a need for a heterojunction solar cell structure and corresponding method for manufacturing that can provide robust grid lines with improved contact resistance characteristics that do not degrade over time. There is a further need for such a structure that can be efficiently manufactured.

### SUMMARY

The described structure and method belong to the field of photovoltaic device manufacturing technology, specifically relating to a structure and preparation method for improving the performance of heterojunction solar cells through stepwise deposition of ITO layers and embedded grid line design. It is particularly suitable for the industrial production of high-efficiency heterojunction (HJT) solar cells.

The described structure and method allows for the decoupling between passivation protection and current transport in HJT solar cells. The method described also allows for low-temperature sacrificial layer process, such that the entire process may be kept below 180° Celsius, thereby avoiding thermal damage to the amorphous silicon layer.

The approach described also uses three-dimensional ohmic contact technology. The main grid lines, or busbar, directly connects to the fine grid lines through holes penetrating the second ITO layer, thereby forming a three-dimensional structure.

A heterojunction solar cell is provided that includes a silicon substrate, a passivation layer overlaying the silicon substrate at a first surface, a first indium tin oxide (ITO) layer overlaying the passivation layer, a second indium tin oxide (ITO) layer overlaying the first ITO layer, and metal grid lines between the first and second ITO layers.

In some embodiments, the heterojunction solar cell further includes a main metal grid line extending through a window in the second ITO layer and connecting the plurality of metal grid lines. In some such embodiments, the plurality of metal grid lines comprise a first metal material and the main metal grid line comprises a second metal material different from the first metal material. In some such embodiments, the first metal material comprises copper and the second metal material comprises a silver paste. In some such embodiments, the first metal material is a copper based composite conductor with a titanium or titanium nitride barrier layer.

In some embodiments utilizing distinct metal materials, the first metal material is applied by photolithography and electroplating prior to application of the second ITO layer and the second metal material is applied by screen printing following the application of the second ITO layer.

In some embodiments, the first ITO layer has a different material composition or thickness than the second ITO layer. In some such embodiments, the first ITO layer has an oxygen partial pressure of 12-15% and the second ITO layer has an oxygen partial pressure of 5-9%. In some embodiments utilizing different ITO layers, the first ITO layer has a thickness of 10-20 nm and the second ITO layer has a thickness of 50-70 nm.

In some embodiments, the solar cell is bifacial and symmetrical, such that a secondary passivation layer overlays the silicon substrate at a second surface opposite the first surface, a secondary first ITO layer overlays the secondary passivation layer, a secondary second ITO layer overlays the secondary first ITO layer, and a secondary plurality of metal grid lines is provided between the secondary first and second ITO layers.

Also provided is a method for manufacturing a heterojunction solar cell. The method includes providing a silicon substrate having a passivation layer on a first surface, depositing a first ITO layer on a surface of the passivation layer, forming a plurality of embedded grid lines on the first ITO layer, patterning a sacrificial layer to define a main grid contact area, depositing a second ITO layer on a surface of the first ITO layer, encapsulating the embedded grid lines, removing the sacrificial layer, and forming at least one main metal grid line in contact with the plurality of embedded grid lines.

In some embodiments, the forming of the plurality of embedded grid lines is by photolithography and electroplating, and the forming of the at least one main grid line is by a method other than photolithography and electroplating. In some such embodiments, the forming of the at least one main grid line is by screen printing the at least one main grid line to form ohmic contact with the plurality of embedded grid lines.

In some embodiments, the plurality of embedded grid lines are formed from copper based composite conductors and the at least one main grid line is formed from a silver paste.

In some embodiments, all steps are performed at temperatures at or below 180° Celsius.

In some embodiments, the sacrificial layer comprises a thermally decomposable polyimide or an alkali-soluble photoresist. In some such embodiments, the sacrificial layer has a decomposition temperature below 180° Celsius.

In some embodiments, the first ITO layer has a different material composition or thickness than the second ITO layer. In some such embodiments, the first ITO layer has an oxygen content of 12-15% and the second ITO layer has an oxygen content of 7-9%. In some embodiments utilizing different ITO layers, the first ITO layer has a thickness of 10-20 nm and the second ITO layer has a thickness of 50-70 nm.

### BRIEF DESCRIPTION OF THE DRAWINGS

FIG. 1 is a schematic diagram of a heterojunction solar cell structure in accordance with this disclosure.

FIG. 2 is an isolated schematic diagram of a portion of the heterojunction solar cell structure of FIG. 1 from a side perspective taken at cut line 2-2.

FIG. 3 is an isolated schematic diagram of a portion of the heterojunction solar cell structure of FIG. 1 from a side perspective taken at cut line 3-3.

FIG. 4 is a flowchart illustrating a method for manufacturing a heterojunction solar cell in accordance with this disclosure.

### DETAILED DESCRIPTION OF THE PREFERRED EMBODIMENTS

The description of illustrative embodiments according to principles of the present invention is intended to be read in connection with the accompanying drawings, which are to be considered part of the entire written description. In the description of embodiments of the invention disclosed herein, any reference to direction or orientation is merely intended for convenience of description and is not intended in any way to limit the scope of the present invention. Relative terms such as “lower,” “upper,” “horizontal,” “vertical,” “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation unless explicitly indicated as such. Terms such as “attached,” “affixed,” “connected,” “coupled,” “interconnected,” and similar refer to a relationship wherein structures are secured or attached to one another either directly or indirectly through intervening structures, as well as both movable or rigid attachments or relationships, unless expressly described otherwise. Moreover, the features and benefits of the invention are illustrated by reference to the exemplified embodiments. Accordingly, the invention expressly should not be limited to such exemplary embodiments illustrating some possible non-limiting combination of features that may exist alone or in other combinations of features; the scope of the invention being defined by the claims appended hereto.

This disclosure describes the best mode or modes of practicing the invention as presently contemplated. This description is not intended to be understood in a limiting sense, but provides an example of the invention presented solely for illustrative purposes by reference to the accompanying drawings to advise one of ordinary skill in the art of the advantages and construction of the invention. In the various views of the drawings, like reference characters designate like or similar parts.

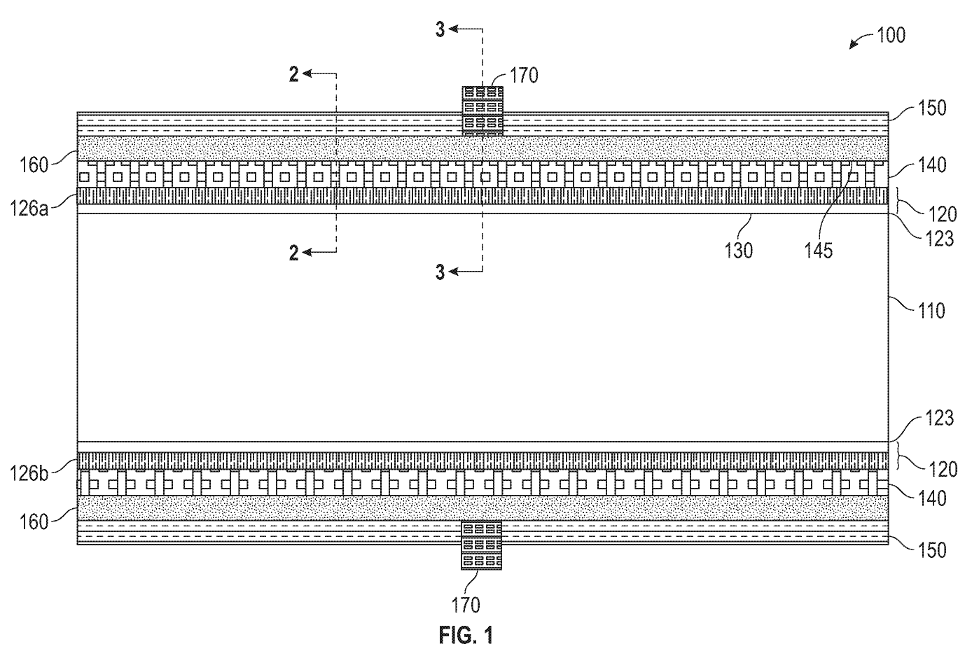

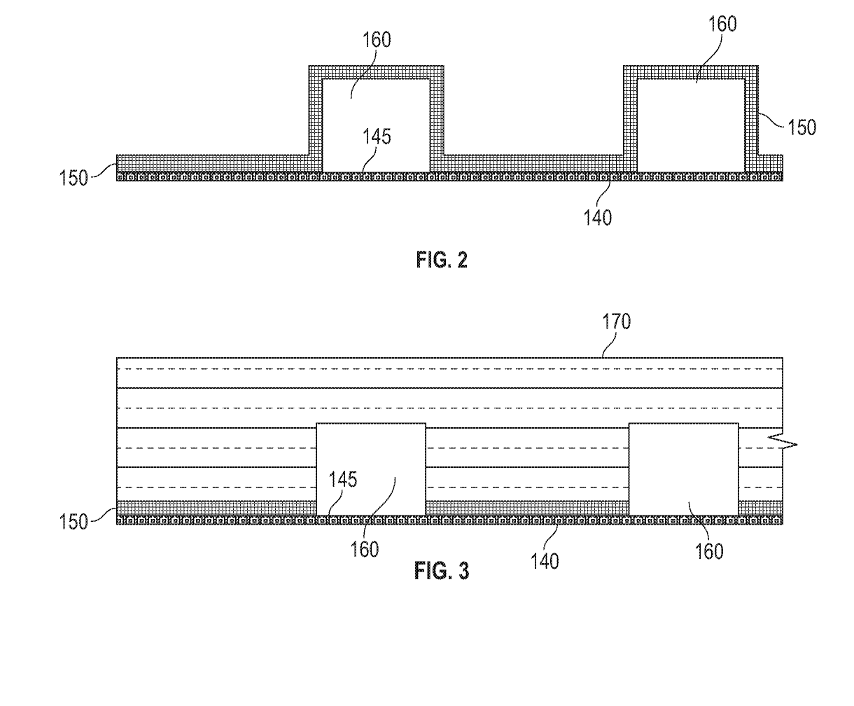

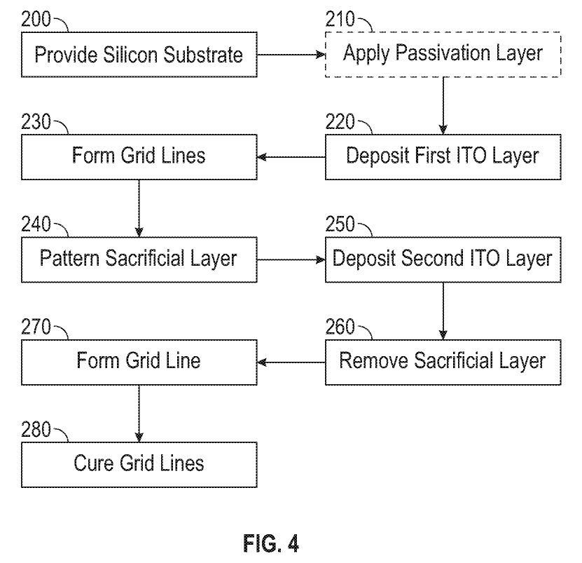

FIG. 1 is a schematic diagram of a heterojunction solar cell 100 structure in accordance with this disclosure. FIG. 2 is an isolated schematic diagram of a portion of the heterojunction solar cell structure 100 of FIG. 1 from a side perspective taken at cut line 2-2. FIG. 3 is an isolated schematic diagram of a portion of the heterojunction solar cell structure 100 of FIG. 1 from a side perspective taken at cut line 3-3. FIG. 4 is a flowchart illustrating a method for manufacturing a heterojunction solar cell 100 in accordance with this disclosure.

As shown, the heterojunction (HJT) solar cell 100 has a silicon substrate 110, a passivation layer 120 overlaying the silicon substrate 100 at a first surface 130 and a plurality of indium tin oxide (ITO) layers 140, 150 overlaying the passivation layer 120.

A first ITO layer 140 overlays the passivation layer 120 and a second ITO layer 150 overlays the first ITO layer. A plurality of grid lines 160, or fingers, are located between the first and second ITO layers 140, 150. The plurality of grid lines 160 are then fully encapsulated between the first and second ITO layers 140, 150.

As shown in FIGS. 2 and 3, the plurality of grid lines 160 are typically spaced apart from each other between the first and second ITO layers 140, 150, such that they are not in contact with each other. Finally, a main metal grid line 170, occasionally referred to as a busbar, extends through the second ITO layer 150 and connects the plurality of metal grid lines 160 to each other. Generally, the discussion below assumes a single busbar 170 and a plurality of grid lines 160. However, it will be understood that additional or repeated structures are contemplated herein.

In manufacturing or otherwise assembling the heterojunction solar cell 100 of FIG. 1, the method begins with providing a silicon substrate 110 (200) having a passivation layer 120 on a first surface 130. In some embodiments, the application of the passivation layer 120 is a step in the process (210), while in other embodiments the silicon substrate 110 is provided with the passivation layer already applied.

In the embodiment shown, the silicon substrate 110 is an n-type monocrystalline silicon wafer, but alternative materials are contemplated as well. The resistivity of such a silicon wafer may be 1-3 Ω·cm, and a thickness may be 160 μm. In some embodiments, the silicon wafer 110 may be finished with alkaline polishing, resulting in a pyramid height of 1.5 μm, and a reflectivity 9.0%.

The passivation layer applied (at 210) may ultimately comprise two layers, with an intrinsic amorphous silicon layer (a-Si:H(i)) followed by a doped amorphous silicon layer (a-Si:H(p) or (n)). Accordingly, the passivation layer 120 applied (at 210) to the front surface 130 may be a 5 nm layer of intrinsic amorphous silicon a-Si:H(i) 123 followed by a 5 nm layer of p-doped amorphous silicon a-Si:H(p) 126a. The back surface may similarly have a 5 nm layer of intrinsic amorphous silicon a-Si:H(i) 123 followed by a 5 nm layer of n-doped amorphous silicon a-Si:H(n) 126b. The application of the passivation layer 120 (at 210) may be by way of plasma-enhanced chemical vapor deposition (PECVD), and may be implemented at a temperature of 180° Celsius and at a pressure of 0.8 Torr.

The method then proceeds with depositing (220) the first indium tin oxide (ITO) layer 140 on the first surface of the passivation layer 120. The first ITO layer 140 may have a first oxygen partial pressure which may be 12-15% during a sputtering process in which the layer is applied. For example, it may have an oxygen partial pressure of 13%. The first ITO layer may be applied by magnetron sputtering and may have a thickness of 10-20 nm, such as 15 nm, and a resulting sheet resistance of 90 Ω/□.

Following the deposition of the first ITO layer 140 (at 220), the method proceeds with forming (230) the plurality of grid lines 160 on a surface 145 of the first ITO layer 140.

The forming of the grid lines 160 (at 230) may be through photolithography and electroplating processes. Accordingly, the forming of the grid lines may involve coating the surface with photoresist (such as AZ 5214, applied at a thickness of 8 μm), followed by exposure (such as at a wavelength of 405 nm with an energy of 180 mJ/cm²) followed by development in order to form grid line trenches. A titanium layer, or a titanium nitride layer, may then be deposited by sputtering (to a thickness of 50 nm) followed by electroplating with copper at a line width of 22 μm, a height of 6 μm, and resulting in a resistivity of 2.3 μΩ·cm. The embedded grid lines 160 resulting are fine grid lines, or fingers, and typically have a line width smaller than 25 μm and applied through a low temperature process.

Following such a forming of grid lines 160 (at 230), a chemical mechanical polishing process (CMP) may be applied. For example, a polishing solution with a pH=4.0 may be applied, resulting in a removal rate of 0.25 μm/min.

Following the forming of the grid lines 160 (at 230), the method proceeds with patterning a sacrificial layer (240) to define a main grid contact area linking the plurality embedded grid lines 160. The sacrificial layer may be formed from photosensitive polyamide, such as HD-3010, with a thickness of 12 μm. Alternatively, an alkali-soluble photoresist may be used. The polyamide may then be patterned by UV exposure using a wavelength of 365 nm with an energy level of 350 mJ/cm²). This may be used to open windows to provide access to the grid lines 160, with apertures sized to be 1.2 mm x 1.2 mm.

The second indium tin oxide (ITO) layer 150 is then deposited (250) on the surface 145 of the first ITO layer 140, thereby fully encapsulating the embedded grid lines 160. Following the application of the second ITO layer 150, the top of the grid lines 160 may be less than 10 nm from the surface of the second ITO layer 150. The second ITO layer 150 may have a second oxygen partial pressure different than the first oxygen partial pressure associated with the first ITO layer 140 during a sputtering process in which the layer is applied. Accordingly, the second oxygen partial pressure may be 5-9%. For example, it may have an oxygen partial pressure of 5%. The second ITO layer 150 may be applied by magnetron sputtering and may have a thickness of 50-70 nm, such as 60 nm, and a resulting sheet resistance of 21 Ω/□. Accordingly, the second ITO layer 150 has a lower oxygen partial pressure than the first ITO layer 140, resulting in a different material composition than the first ITO layer. The second ITO layer 150 also has a larger thickness than the first ITO layer 140.

It is noted that the oxygen partial pressure during sputtering may not correspond to the resulting oxygen content of the ITO material. Accordingly, for the second layer, the atomic percentage of oxygen in the ITO material following sputtering may be 7-9%.

As shown in FIGS. 2 and 3, the thickness of the second ITO layer 150, measured in nanometers, may be substantially smaller than the thickness of the grid line 160, measured in micrometers. As such, in locations where the second ITO layer 150 is present, and is not blocked by the sacrificial layer during production, the grid line is fully enclosed by the second ITO layer, as shown in FIG. 2. In contrast, where the sacrificial layer is applied, thereby preventing the second ITO layer 150 from coating the grid line 160, the grid line extends above the second ITO layer through a resulting window, as shown in FIG. 3.

The sacrificial layer is then removed (260) providing access to the embedded grid lines 160 through the second ITO layer 150. Such removal may be thermal decomposition at 180° Celsius with a nitrogen flow rate of 5 L/min for 25 minutes. This may be followed by a mechanical removal of residues.

The method may then proceed by forming (270) at least one main metal grid line 170, or busbar, in contact with each of the plurality of embedded grid lines 160 through the windows left by the removal of the sacrificial layer (at 260). The embedded grid lines 160 may be formed from a first metal material or composition different than the main metal grid line 170. The embedded grid lines 160 may similarly be formed using a different deposition technique than the main metal grid line 170.

Accordingly, as discussed above, the embedded grid lines 160 may be formed from copper based composite conductors, and may be applied (at 230) by photolithography and electroplating. The main grid line 170, or busbar, may be formed from a low-temperature silver paste, such as Dupont PV18B, and may be screen printed with a line width of 1.2 mm and cured (at 280) at a relatively low temperature, such as 170° Celsius, but generally below 180° Celsius.

Because the main grid line 170 is applied to a location at which the sacrificial layer was removed (at 260), the main metal grid line 170 extends through the second ITO layer 150 and connects the plurality of metal grid lines 160 which are otherwise fully embedded between the two ITO layers 140, 150. The resulting main metal grid line 170 or grid lines form a three-dimensional ohmic contact with the fine grid lines 160 through the sacrificial layer window described above. This results in a three-dimensional interconnected structure.

In some embodiments, all steps are performed at temperatures at or below 180° Celsius, so as to avoid damaging the amorphous silicon passivation layers.

In some embodiments, the contact resistance associated with the structure and method described is reduced to 0.32 mΩ·cm². The absolute cell efficiency may then be increased by .63% and grid line material cost may be reduced by 53%, since this approach allows copper to replace some of the silver paste otherwise used.

In some embodiments, such as that shown, the heterojunction solar cell 100 may be bifacial and symmetrical, other than doping characteristics. Accordingly, as discussed above, the passivation layer 120 may overlay the first surface 130 of the silicon substrate 110 and a similar passivation layer 120 may overlay a second surface of the silicon substrate opposite the first surface 130. As discussed above, the passivation layers 120 on the front face and the back face of the silicon substrate 110 may each have an identical intrinsic amorphous silicon a-Si:H(i) 123 and may differ in terms of a secondary doped layer 126a, b. Accordingly, the front surface may have a 5 nm layer of p-doped amorphous silicon a-Si:H(p) 126a and the back surface may have a similar layer of intrinsic amorphous silicon a-Si:H(i) 123 followed by a 5 nm layer of n-doped amorphous silicon a-Si:H(n) 126b.

The back surface and corresponding passivation layer 120 may be overlayed with a secondary first ITO layer 140 and a secondary second ITO layer 150 with a secondary plurality of metal grid lines 160 provided between the secondary first and second ITO layers. Similarly, a main metal grid line 170 may extend through the secondary second ITO layer 150 on the back surface of the heterojunction solar cell 100. Similarly, the method described may similarly be applied to the front and back surface in a similar manner, thereby providing a bifacial heterojunction solar cell 100.

While the present invention has been described at some length and with some particularity with respect to the several described embodiments, it is not intended that it should be limited to any such particulars or embodiments or any particular embodiment, but it is to be construed with references to the appended claims so as to provide the broadest possible interpretation of such claims in view of the prior art and, therefore, to effectively encompass the intended scope of the invention. Furthermore, the foregoing describes the invention in terms of embodiments foreseen by the inventor for which an enabling description was available, notwithstanding that insubstantial modifications of the invention, not presently foreseen, may nonetheless represent equivalents thereto.

What is claimed is:

1. A heterojunction solar cell comprising:
a silicon substrate;
a passivation layer overlaying the silicon substrate at a first surface;
a first indium tin oxide (ITO) layer overlaying the passivation layer;
a second indium tin oxide (ITO) layer overlaying the first ITO layer; and
a plurality of metal grid lines between the first and second ITO layers.

2. The heterojunction solar cell of claim 1 further comprising a main metal grid line extending through a window in the second ITO layer and connecting the plurality of metal grid lines.

3. The heterojunction solar cell of claim 2, wherein the plurality of metal grid lines comprise a first metal material and the main metal grid line comprises a second metal material different from the first metal material.

4. The heterojunction solar cell of claim 3, wherein the first metal material comprises copper and the second metal material comprises a silver paste.

5. The heterojunction solar cell of claim 4, wherein the first metal material is a copper based composite conductor with a titanium or titanium nitride barrier layer.

6. The heterojunction solar cell of claim 3, wherein the first metal material is applied by photolithography and electroplating prior to application of the second ITO layer and wherein the second metal material is applied by screen printing following the application of the second ITO layer.

7. The heterojunction solar cell of claim 1, wherein the first ITO layer has a different material composition or thickness than the second ITO layer.

8. The heterojunction solar cell of claim 7, wherein the first ITO layer has an oxygen partial pressure of 12-15% and the second ITO layer has an oxygen partial pressure of 5-9%.

9. The heterojunction solar cell of claim 7, wherein the first ITO layer has a thickness of 10-20 nm and the second ITO layer has a thickness of 50-70 nm.

10. The heterojunction solar cell of claim 1, wherein the solar cell is bifacial and symmetrical, such that a secondary passivation layer overlays the silicon substrate at a second surface opposite the first surface, a secondary first ITO layer overlays the secondary passivation layer, a secondary second ITO layer overlays the secondary first ITO layer, and a secondary plurality of metal grid lines is provided between the secondary first and second ITO layers.

11. A method for manufacturing a heterojunction solar cell comprising:
providing a silicon substrate having a passivation layer on a first surface;
depositing a first ITO layer on a surface of the passivation layer;
forming a plurality of embedded grid lines on the first ITO layer;
patterning a sacrificial layer to define a main grid contact area;
depositing a second ITO layer on a surface of the first ITO layer, encapsulating the embedded grid lines;
removing the sacrificial layer; and
forming at least one main metal grid line in contact with the plurality of embedded grid lines.

12. The method of claim 11, wherein the forming of the plurality of embedded grid lines is by photolithography and electroplating, and wherein the forming of the at least one main grid line is by a method other than photolithography and electroplating.

13. The method of claim 12, wherein the forming of the at least one main grid line is by screen printing the at least one main grid line to form ohmic contact with the plurality of embedded grid lines.

14. The method of claim 11, wherein the plurality of embedded grid lines are formed from copper based composite conductors and wherein the at least one main grid line is formed from a silver paste.

15. The method of claim 11, wherein all steps are performed at temperatures at or below 180° Celsius.

16. The method of claim 11, wherein the sacrificial layer comprises a thermally decomposable polyimide or an alkali-soluble photoresist.

17. The method of claim 16, wherein the sacrificial layer has a decomposition temperature below 180° Celsius.

18. The method of claim 11, wherein the first ITO layer has a different material composition or thickness than the second ITO layer.

19. The method of claim 18, wherein the first ITO layer has an oxygen content of 12-15% and the second ITO layer has an oxygen content of 7-9%.

20. The method of claim 18, wherein the first ITO layer has a thickness of 10-20 nm and the second ITO layer has a thickness of 50-70 nm.
